(19) United States
(12) Patent Application Publication
(10) Pub. No.: US 2025/0275489 A1
(43) Pub. Date: Aug. 28, 2025

(54) STACKED SYNAPTIC ARRAY AND METHOD OF MANUFACTURING THE SAME

(71) Applicants: POSTECH RESEARCH AND BUSINESS DEVELOPMENT FOUNDATION, Pohang-si (KR); KYUNGPOOK NATIONAL UNIVERSITY INDUSTRY-ACADEMIC COOPERATION FOUNDATION, Daegu (KR)

(72) Inventors: Seyoung KIM, Pohang-si (KR); Jiyong WOO, Daegu (KR); Hyunjeong KWAK, Daejeon (KR); Jun Young CHOI, Pohang-si (KR)

(21) Appl. No.: 19/006,707

(22) Filed: Dec. 31, 2024

(30) Foreign Application Priority Data
Feb. 28, 2024 (KR) 10-2024-0028949

(51) Int. Cl. H10N 70/20; H10B 63/00; H10N 70/00

(52) U.S. Cl. CPC H10N 70/253; H10B 63/30; H10N 70/023; H10N 70/026; H10N 70/24; H10N 70/883

(57) ABSTRACT

A stacked synaptic array includes a plurality of drain lines extending along a first direction, a plurality of source lines spaced apart from the drain lines through an insulating layer and extending along a second direction that intersects perpendicularly to the first direction, a vertical pillar-shaped channel region penetrating the drain line, the insulating layer, and the source line in a region where the drain line and the source line intersect, a gate stack formed in the channel region, and a gate line connecting gate stacks to each other above the gate stacks, and the drain lines and the source lines have a repeatedly stacked structure.

### CROSS-REFERENCE TO RELATED APPLICATION

The present application claims the benefit of priority to Korean Patent Application No. 10-2024-0028949 filed on Feb. 28, 2024, in the Korean Intellectual Property Office. The aforementioned application is hereby incorporated by reference in its entirety.

### TECHNICAL FIELD

The present disclosure relates to a stacked synaptic array and a method of manufacturing the same and, more particularly, to a three-dimensional stacked synaptic array that implements in a stacked manner a neuromorphic system in which a channel and a gate stack are implemented in the shape of a pillar, and a method of manufacturing the three-dimensional stacked synaptic array.

### BACKGROUND

A deep learning operation accelerator, a matrix-vector operation accelerator, and an analog deep learning training accelerator based on a cross-point array composed of a non-volatile memory may be applied to various array architectures based on a 3-terminal memory device, and may be applied to various devices using array-based artificial intelligence.

A vertically stacked synaptic array may be used in artificial intelligence and neuromorphic computing, and may be used in a wide range of applications from accelerating learning and inference tasks for a deep learning model to robotics, neuroscience, the Internet of Things, autonomous vehicles, security and pattern recognition, and quantum computing.

Neural network learning, which mimics the parallel computing processing of the brain, performs learning and inference processes through a vector-matrix operation and an outer product operation, and the cross-point array with perpendicularly crossed electrodes is optimized for the vector-matrix operation. Therefore, it is predicted that performing artificial intelligence operations using the cross-point array can accelerate computations by hundreds to thousands of times compared to existing digital hardware.

An existing planar 3-terminal cross-point array is problematic in that its area is larger compared to a 2-terminal cross-point array. The 2-terminal based cross-point array has the unit area of 4F², while the 3-terminal based cross-point array has the unit area of at least 12F². In the case of deep learning, the larger and deeper a hidden layer, the better the learning. To this end, it is essential to expand the cross-point array. As a scale increases, the 3-terminal based array requires at least three times more area compared to the 2-terminal based array, so a solution is needed to improve area efficiency

### [National Research and Development Project Supporting the Present Invention]

[Project Serial No] 1415187361
[Task number] 00236568
[Name of department] Ministry of Trade, Industry and Energy
[Task management (professional) institution name] (Korea Planning & Evaluation Institute of Industrial Technology)
[Research project name] (Korea Semiconductor Research Consortium support program)
[Research Task Name] Development of CMOS-compatible, High-performance for Storage-class Memory and Deep Learning Accelerator
[Name of task performing organization] POSTECH Research and Business Development Foundation
[Research Period] 2023 Apr. 1˜2023 Dec. 31

### [National Research and Development Project Supporting the Present Invention]

[Project Serial No] 1415187475
[Task number] 00231956
[Name of department] Ministry of Trade, Industry and Energy
[Task management (professional) institution name] (Korea Planning & Evaluation Institute of Industrial Technology)
[Research project name] (Korea Semiconductor Research Consortium support program)
[Research Task Name] Co-Optimization of Tiki-Taka Algorithm and High-Performance Synaptic Devices for Neuromorphic In-Memory Computing Process or Development
[Name of task performing organization] Seoul National University R&DB Foundation
[Research Period] 2023 Apr. 1˜2023 Dec. 31

### PRIOR ART DOCUMENT

### Patent Document

(Patent Document 1) Korean Patent Publication No. 10-2019-0131403 (2019 Nov. 26)

### SUMMARY

In view of the above, the present disclosure provides a stacked synaptic array and a method of manufacturing the same, in which a neuromorphic system where a channel and a gate stack are arranged in a pillar shape is implemented in a three-dimensional stacked manner, resulting in an excellent degree of integration and improved operational reliability.

According to an embodiment of the present disclosure, a stacked synaptic array composed of a vertically structured 3-terminal electrochemical memory device may include a plurality of drain lines extending along a first direction, a plurality of source lines disposed to be spaced apart from the drain lines through an insulating layer, and extending along a second direction that intersects perpendicularly to the first direction, a vertical pillar-shaped channel region penetrating the drain line, the insulating layer, and the source line in a region where the drain line and the source line intersect, and surrounded by the insulating layer, a gate stack formed in the channel region, and a gate line connecting gate stacks above the gate stacks, and the drain lines and the source lines may have a repeatedly stacked structure, and the drain lines and the source lines of each layer may intersect to form a plurality of intersection points.

Each of the drain lines and the source lines may include any one material selected from copper, nickel, iron, chromium, titanium, zinc, lead, gold, silver, and tungsten.

The channel region may include a hole formed therein, and a channel material with a predetermined thickness may be deposited on an inner surface of the hole.

The drain line and the source line may be arranged at a predetermined interval in an upper direction with the channel region interposed therebetween.

The gate stack may include an electrolyte layer, an ion reservoir, and a gate electrode, the electrolyte layer may be composed of any one material selected from HfOx, titanium nitride, tantalum nitride, tungsten nitride, hafnium nitride, zirconium nitride, and a combination thereof, and the gate electrode may include a metal layer and a barrier metal layer.

The gate line may intersect the drain line, may be formed in a shape of a line extending along the same direction as the source line, and may be formed in a shape of a cap with a convex upper portion at a top of a structure in which the drain lines and the source lines are repeatedly stacked.

The vertically structured 3-terminal electrochemical memory device may be arranged in a shape of a cross-point array to form a single-layer vertically structured synaptic array.

The neuromorphic semiconductor device may further include an accelerator structure provided between the gate stack formed over the substrate and the channel region, and the accelerator structure may apply an external voltage to increase speed of an electrochemical reaction.

According to another embodiment of the present disclosure, a method of manufacturing a stacked synaptic array composed of a vertically structured 3-terminal electrochemical memory device may include forming a stacked structure by repeatedly stacking a drain line, an insulating layer, and a source line in this order over a semiconductor substrate, forming a hole that defines a channel region by selectively etching the source line, the insulating layer, and the drain line in the stacked structure, forming the channel region by depositing a channel material on an inner surface of the hole, forming a gate stack that fills the hole in which the channel material is deposited, and forming a gate line that connects gate stacks.

Each of the drain line and the source line may be formed of any one material selected from aluminum, copper, nickel, iron, chromium, titanium, zinc, lead, gold, silver, and tungsten.

The drain line and the source line may intersect perpendicularly, and the drain line, the insulating layer, and the source line may be repeatedly stacked in multiple layers according to a stack height.

In repeatedly stacking the drain line, the insulating layer, and the source line, the insulating layer may be positioned at a top.

The channel material may be deposited using sputtering or atomic layer deposition, and the channel material may be formed of any one material selected from WO3, TiO2, ZrO2, ZnO, PCMO, and a combination thereof.

The gate stack may include an electrolyte layer, an ion reservoir, and a gate electrode, and the gate electrode may include a metal layer and a barrier metal layer.

The gate line may connect a vertical pillar composed of the channel material and the gate stack at a top of the stacked structure, perpendicularly intersect the drain line, and be formed in a shape of extending along the same direction as the source line.

The disclosed technology may have the following effects. However, it should not be construed that the scope of the disclosed technology is limited thereto, as it does not mean that a specific embodiment must include all or only the following effects.

A stacked synaptic array using a vertically structured 3-terminal electrochemical memory device and a method of manufacturing the same according to an embodiment of the present disclosure are advantageous in that a gate, a source electrode, and a drain electrode are sequentially arranged in a channel region in the shape of a vertical pillar in a neuromorphic system, so it is excellent in terms of area efficiency and can provide a higher degree of integration.

Further, a stacked synaptic array using a vertically structured 3-terminal electrochemical memory device and a method of manufacturing the same according to an embodiment of the present disclosure are advantageous in that a switching speed can be improved by reducing an ion movement distance within a single device, and power consumption can be reduced by using a shorter wire and fewer buffers, thereby achieving low-power and high-efficiency in-memory computing.

### BRIEF DESCRIPTION OF THE DRAWINGS

FIG. 1 illustrates a general fully connected layer neural network.

FIG. 2 is a diagram showing a 3-terminal based 32×32 synaptic array to which an artificial neural network may be applied.

FIGS. 3A and 3B illustrate the structure and driving method of a 3-terminal memory device based on ECRAM.

FIG. 4 illustrates a vertically structured 3-terminal electrochemical memory device according to an embodiment of the present disclosure.

FIG. 5 illustrates a stacked synaptic array composed of a vertically structured 3-terminal electrochemical memory device according to an embodiment of the present disclosure.

FIGS. 6A to 6J are sectional views illustrating a method of manufacturing a stacked synaptic array according to an embodiment of the present disclosure.

### DETAILED DESCRIPTION

Specific structural or functional descriptions in the embodiments of the present disclosure are only for description of the embodiments of the present disclosure. The descriptions should not be construed as being limited to the embodiments described in the specification or application. That is, the present disclosure may be embodied in many different forms, but should be construed as covering modifications, equivalents or alternatives falling within ideas and technical scopes of the present disclosure. Since the objects or effects set forth in the present disclosure do not mean that a specific embodiment must include all of them or only such effects, the scope of the present disclosure should not be understood as being limited thereto.

Meanwhile, the meanings of the terms described in this application should be understood as follows.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be understood that when an element is referred to as being “coupled” or “connected” to another element, it can be directly coupled or connected to the other element or intervening elements may be present therebetween. In contrast, it should be understood that when an element is referred to as being “directly coupled” or “directly connected” to another element, there are no intervening elements present. Other expressions that explain the relationship between elements, such as “between”, “directly between”, “adjacent to” or directly adjacent to” should be construed in the same way.

In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

The identification codes (e.g., a, b, c, etc.) in each step are used for convenience of explanation and do not describe the order of each step. The steps may occur in a different order, unless the context clearly dictates otherwise. That is, the steps may be performed in a specified order, may be performed substantially simultaneously, or may be performed in reverse order.

The present disclosure can be implemented as a computer-readable code on a computer-readable recording medium, and the computer-readable recording medium includes all kinds of recording devices that store data that can be read by a computer system. Examples of the computer-readable recording medium include ROM, RAM, CD-ROM, magnetic tape, floppy disks, and optical data storage devices. Further, the computer-readable recording medium can be distributed across network-connected computer systems, allowing the computer-readable code to be stored and executed in a distributed manner.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art and will not be interpreted in an idealized or overly formal sense unless expressly so defined herein.

Hereinafter, exemplary embodiments of the present disclosure will be explained in detail with reference to the accompanying drawings. The same reference numerals are used throughout the drawings to designate the same or similar components. A duplicated description of the same components will be omitted herein.

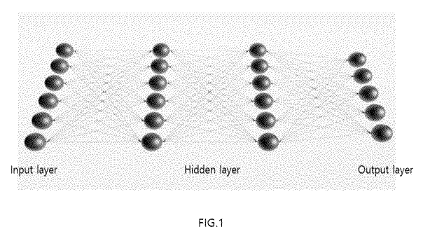

FIG. 1 illustrates a general fully connected layer neural network.

Referring to FIG. 1, a unit where multiple neurons are gathered is called a layer, and a fully connected layer structure is a structure in which all cases in each layer are connected. If neurons in an input layer and neurons in an output layer are connected in all possible combinations, this is called a fully connected layer. The artificial neural network includes an input layer, a hidden layer, and an output layer.

The input layer receives input and passes it on to a next layer, the hidden layer. The hidden layer is a fully connected layer that is connected to the input layer, and may be referred to as a key layer that may solve a complex problem. Finally, the output layer is a fully connected layer located after the hidden layer, and is used to transmit an output signal to the outside of a neural network. The function of the neural network is determined by an activation function of the output layer. Here, only two hidden layers are shown, and a training process is composed of a forward pass and a backward pass. Subsequently, a weight update is performed. At this time, a matrix operation accounts for the largest proportion.

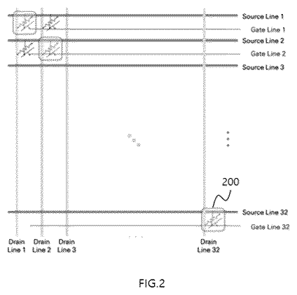

FIG. 2 is a diagram showing a 3-terminal based 32×32 synaptic array to which an artificial neural network may be applied.

Referring to FIG. 2, the synaptic array includes a plurality of source lines extending from a peripheral circuit region, and a plurality of drain lines configured to intersect the source lines. A 3-terminal electrochemical memory device 200 that may control conductivity is disposed at the intersection of the source line and the drain line.

An artificial neural network device composed of such an array has a high proportion of matrix operations, and the values of each element of the matrix of the operation may be replaced with the conductivity of each memory device, and a matrix product may be calculated by integrating the current flowing out by applying a voltage pulse.

At this time, since the forward and backward passes should be performed with a single synaptic array, the source line and the drain line may be switched depending on a pass direction.

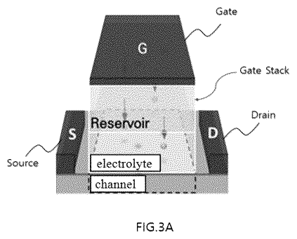

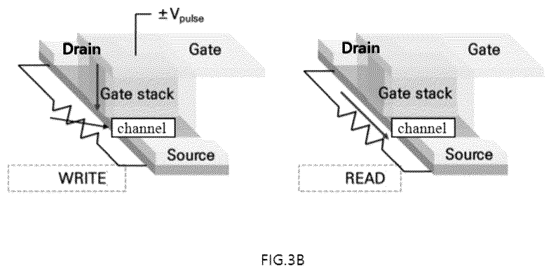

FIGS. 3A and 3B illustrate the structure and driving method of a 3-terminal memory device based on ECRAM.

First, referring to FIG. 3A, the ECRAM-based 3-terminal memory device has a source region and a drain region on an upper portion of a semiconductor substrate, and a channel region is provided between the source region and the drain region. A gate stack including an electrolyte and a reservoir may be provided above the channel region, and may include a gate electrode layer.

Referring to FIG. 3B, the 3-terminal electrochemical memory device applies voltage to a gate electrode to induce the movement of ions between the gate electrode and the channel region, thereby changing the conductivity of a channel material between the source region and the drain region. At this time, examples of ions include Li ions, hydrogen ions, oxygen ions, copper ions, and Na ions. It is preferable that the channel material be formed of WO3, PCMO, etc., whose conductivity may change depending on the amount of ions. The reservoir is used as an ion reservoir, an electrolyte layer is used between the gate and the channel region to facilitate the passage of ions but restrict the passage of current, thereby minimizing current leakage. Using these characteristics, an inference process may be performed by applying a voltage between the source and the drain, and a weight update process may be performed by applying a pulse to the gate.

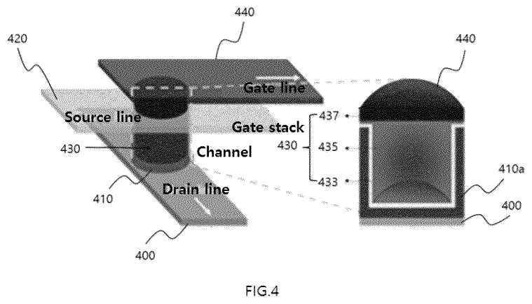

FIG. 4 illustrates a vertically structured 3-terminal electrochemical memory device according to an embodiment of the present disclosure.

Referring to FIG. 4, the vertically structured 3-terminal electrochemical memory device may include a drain electrode 400, a channel region 410, a source electrode 420, a gate stack 430, and a gate electrode 440.

To be more specific, a line-shaped drain electrode 400 extending in the direction of the drain line is provided on the upper portion of the semiconductor substrate. The source electrode 420 and the drain electrode 400 may include at least one metal material selected from aluminum, copper, nickel, iron, chromium, titanium, zinc, lead, gold, silver, and tungsten.

A channel region 410 perpendicular to the drain electrode 400 is provided on the drain electrode 400. Preferably, a lower portion of the channel region 410 contacts the drain electrode 400, and the channel region 410 is formed in the shape of a vertical pillar having a hole therein.

Preferably, the channel region 410 is in the shape of a vertical pillar where an upper surface, a lower surface, and an inner surface thereof are surrounded by a channel material 410a of a certain thickness. The channel material 410a may include a metal oxide, and may be formed of, for example, any one material selected from WO3, TiO2, ZrO2, PCMO, and a combination thereof.

The source electrode 420 is spaced apart from the drain electrode 400 by a predetermined distance. More preferably, it is positioned at a predetermined distance from the drain electrode 400 toward the upper side of the channel region 410.

The gate stack 430 may be provided on an upper portion of the channel region 410, and may include an electrolyte layer 433, an ion reservoir 435, and a gate electrode 437. The electrolyte layer 433 may be made of HfOx, titanium nitride, tantalum nitride, tungsten nitride, hafnium nitride, and zirconium nitride. The gate electrode 437 may be composed of a metal layer and a barrier metal layer. For example, the barrier metal layer may be made of HfO_{X}, hafnium oxide (HfO₂), titanium nitride, tantalum nitride, tungsten nitride, hafnium nitride, and zirconium nitride. The metal layer may be formed of any one selected from tungsten, copper, hafnium, zirconium, titanium, tantalum, aluminum, ruthenium, palladium, platinum, cobalt, nickel, and conductive metal nitrides or a combination thereof.

The gate line 440 may connect the gate stacks, and may be formed in the shape of a cap with a convex upper portion.

FIG. 5 illustrates a stacked synaptic array composed of a vertically structured 3-terminal electrochemical memory device according to an embodiment of the present disclosure.

Referring to FIG. 5, a stacked 3-terminal cross-point array according to an embodiment of the present disclosure may have access to the device through the gate line, the source line, and the drain line.

The drain line may be formed in the shape of a line extending along a first direction. Further, the source line may be spaced apart from the drain line by a predetermined distance, and be formed in the shape of a line extending along a second direction perpendicular to the drain line. Drain lines and source lines are repeatedly arranged with an insulating layer therebetween, and a gate stack in the form of a vertical pillar is disposed through a section where the drain line and the source line intersect.

The gate line is disposed on the top to connect the gate stacks. The gate line may be perpendicular to the drain line, and may be formed in the shape of a line extending along the same direction as the source line.

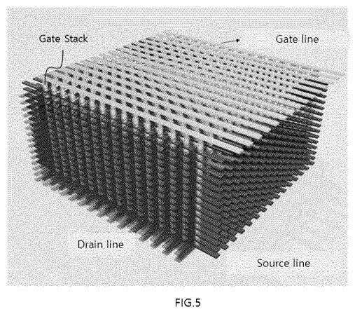

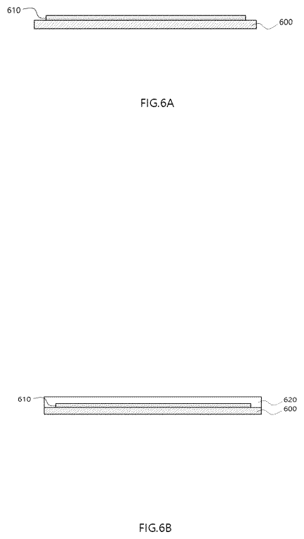

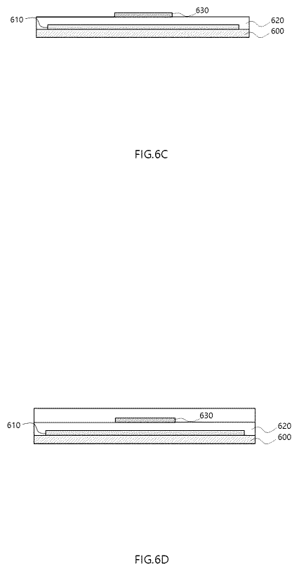

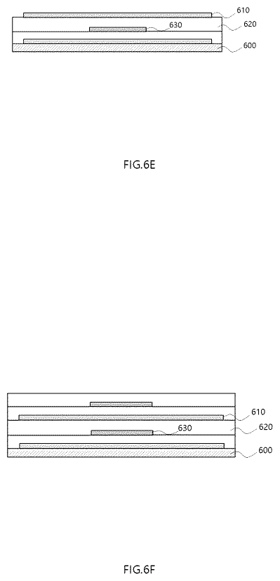

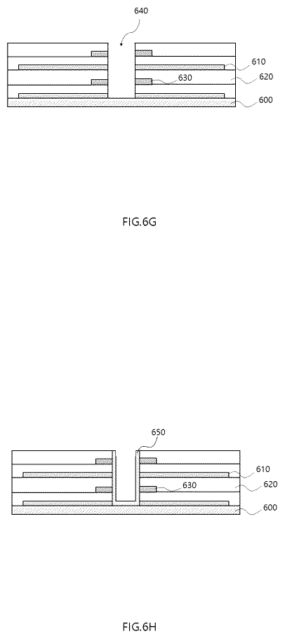

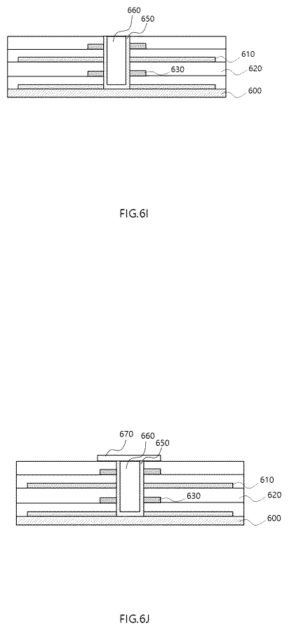

FIGS. 6A to 6J are sectional views illustrating a method of manufacturing a stacked synaptic array according to an embodiment of the present disclosure.

First, referring to FIG. 6A, a drain line 610 is formed on the upper portion of a semiconductor substrate 600. The drain line 610 may include at least one metal material selected from aluminum, copper, nickel, iron, chromium, titanium, zinc, lead, gold, silver, and tungsten.

Referring to FIG. 6B, an insulating layer 620 is formed on the upper portion of the drain line 610. Here, the insulating layer 620 means a material layer other than the channel, so it is not necessarily limited to the insulating layer.

Subsequently, referring to FIG. 6C, a source line 630 that vertically intersects the drain line 610 is formed on the upper portion of the insulating layer 620. The source line 630 may include at least one metal material selected from among aluminum, copper, nickel, iron, chromium, titanium, zinc, lead, gold, silver, and tungsten.

Referring to FIGS. 6D to 6F, the insulating layer 620 is formed again on the upper portion of the source line 630, and the drain line 610 is formed again in the vertical direction. Source and drain lines may be repeatedly formed depending on a desired stacking height.

Referring to FIG. 6G, a mask pattern (not shown) that opens the channel region is formed on the upper portion of the insulating layer 620 formed at the top.

Next, the insulating layers 620, the source lines 630, and the drain lines 610 that are repeatedly stacked using the mask pattern as an etching mask are etched to form a hole 640 through which the semiconductor substrate 600 is exposed, and then the mask pattern is removed.

Referring to FIG. 6H, a channel material 650 is deposited over the entire surface of the hole 640. At this time, it is preferable to deposit the channel material of a predetermined thickness on the lower surface and inner surface of the hole 640 using sputtering or atomic layer deposition. The channel material 650 may include a metal oxide, and may be formed of, for example, WO3, TiO2, ZrO2, ZnO, PCMO, etc.

Referring to FIG. 6I, a gate stack 660 is formed inside the hole 640 on which the channel material 650 is deposited. The gate stack 660 may include an electrolyte layer, an ion reservoir, and a gate electrode, and the gate electrode may be composed of a metal layer and a barrier metal layer. For example, the barrier metal layer may be formed of hafnium oxide (HfO₂), titanium nitride, tantalum nitride, tungsten nitride, hafnium nitride, and zirconium nitride, while the metal layer may be formed of any one selected from tungsten, copper, hafnium, zirconium, titanium, tantalum, aluminum, ruthenium, palladium, platinum, cobalt, nickel, and conductive metal nitrides, or a combination thereof.

Finally, referring to FIG. 6J, a gate line 670 is formed to contact the gate stack 660 and connect vertical pillars formed of the channel material 650 and the gate stack 660. Preferably, the gate line 670 is in the shape of a line that perpendicularly intersects the drain line 610 and extends in the same direction as the source line 630.

As described above, a stacked synaptic array using a vertically structured 3-terminal electrochemical memory device and a method of manufacturing the same according to an embodiment of the present disclosure are configured so that a gate, a source electrode, and a drain electrode are sequentially arranged in a channel region in the shape of a vertical pillar, so it is excellent in terms of area efficiency and can provide a higher degree of integration. Further, a switching speed can be improved by reducing an ion movement distance within a single device, and power consumption can be reduced by using a shorter wire and fewer buffers, thereby achieving low-power and high-efficiency in-memory computing.

Although the present disclosure was provided above in relation to specific embodiments shown in the drawings, it is apparent to those skilled in the art that the present disclosure may be changed and modified in various ways without departing from the scope of the present disclosure, which is described in the following claims.

[Detailed Description of Main Elements]

| | |
|---|---|
| 400, 610: drain line | 410: channel region |
| 410a, 650: channel material | 420, 630: source line |
| 430, 660: gate stack | 433: electrolyte layer |
| 435: ion reservoir | 437: gate electrode |
| 440, 670: gate line | 600: semiconductor substrate |
| 640: hole | |

What is claimed is:

1. A stacked synaptic array composed of a vertically structured 3-terminal electrochemical memory device, the stacked synaptic array comprising:
a plurality of drain lines extending along a first direction;
a plurality of source lines disposed to be spaced apart from the drain lines through an insulating layer, and extending along a second direction that intersects perpendicularly to the first direction;
a vertical pillar-shaped channel region penetrating the drain line, the insulating layer, and the source line in a region where the drain line and the source line intersect, and surrounded by the insulating layer;
a gate stack formed in the channel region; and
a gate line connecting gate stacks above the gate stacks,
wherein the drain lines and the source lines have a repeatedly stacked structure, and the drain lines and the source lines of each layer intersect to form a plurality of intersection points.

2. The stacked synaptic array of claim 1, wherein each of the drain lines and the source lines comprises any one material selected from copper, nickel, iron, chromium, titanium, zinc, lead, gold, silver, and tungsten.

3. The stacked synaptic array of claim 1, wherein the channel region comprises a hole formed therein, and a channel material with a predetermined thickness is deposited on an inner surface of the hole.

4. The stacked synaptic array of claim 1, wherein the drain line and the source line are arranged at a predetermined interval in an upper direction with the channel region interposed therebetween.

5. The stacked synaptic array of claim 1, wherein the gate stack comprises an electrolyte layer, an ion reservoir, and a gate electrode, the electrolyte layer is composed of any one material selected from HfOx, titanium nitride, tantalum nitride, tungsten nitride, hafnium nitride, zirconium nitride, and a combination thereof, and the gate electrode comprises a metal layer and a barrier metal layer.

6. The stacked synaptic array of claim 1, wherein the gate line intersects the drain line, is formed in a shape of a line extending along the same direction as the source line, and is formed in a shape of a cap with a convex upper portion at a top of a structure in which the drain lines and the source lines are repeatedly stacked.

7. The stacked synaptic array of claim 1, wherein the vertically structured 3-terminal electrochemical memory device is arranged in a shape of a cross-point array to form a single-layer vertically structured synaptic array.

8. The stacked synaptic array of claim 1, further comprising:
an accelerator structure provided between the gate stack formed over the substrate and the channel region,
wherein the accelerator structure applies an external voltage to increase speed of an electrochemical reaction.

9. A method of manufacturing a stacked synaptic array composed of a vertically structured 3-terminal electrochemical memory device, the method comprising:
forming a stacked structure by repeatedly stacking a drain line, an insulating layer, and a source line in this order over a semiconductor substrate;
forming a hole that defines a channel region by selectively etching the source line, the insulating layer, and the drain line in the stacked structure;
forming the channel region by depositing a channel material on an inner surface of the hole;
forming a gate stack that fills the hole in which the channel material is deposited; and
forming a gate line that connects gate stacks.

10. The method of claim 9, wherein each of the drain line and the source line is formed of any one material selected from aluminum, copper, nickel, iron, chromium, titanium, zinc, lead, gold, silver, and tungsten.

11. The method of claim 9, wherein the drain line and the source line intersect perpendicularly, and the drain line, the insulating layer, and the source line are repeatedly stacked in multiple layers according to a stack height.

12. The method of claim 9, wherein, in repeatedly stacking the drain line, the insulating layer, and the source line, the insulating layer is positioned at a top.

13. The method of claim 9, wherein the channel material is deposited using sputtering or atomic layer deposition, and the channel material is formed of any one material selected from WO3, TiO2, ZrO2, ZnO, PCMO, and a combination thereof.

14. The method of claim 9, wherein the gate stack comprises an electrolyte layer, an ion reservoir, and a gate electrode, and the gate electrode comprises a metal layer and a barrier metal layer.

15. The method of claim 9, wherein the gate line connects a vertical pillar composed of the channel material and the gate stack at a top of the stacked structure, perpendicularly intersects the drain line, and is formed in a shape of extending along the same direction as the source line.
